(19) United States
(12) Patent Application Publication
(10) Pub. No.: US 2010/0155721 A1
(43) Pub. Date: Jun. 24, 2010

(54) THIN FILM TRANSISTOR ARRAY SUBSTRATE AND METHOD OF FABRICATING THE SAME

(76) Inventors: Je-Hun LEE, Seoul (KR); Tae-Hyung IHN, Seoul (KR); Dong-Hoon LEE, Seoul (KR); Do-Hyun KIM, Seoul (KR)

Correspondence Address: Innovation Counsel LLP, 21771 Stevens Creek Blvd, Ste. 200A, Cupertino, CA, 95014, US

(21) Appl. No.: 12/645,433

(22) Filed: Dec. 22, 2009

(30) Foreign Application Priority Data
Dec. 24, 2008 (KR) 10-2008-0133624

(51) Int. Cl. H01L 29/786; H01L 21/34

(52) U.S. Cl. 257/43; 438/104; 257/E29.273; 257/E21.46

(57) ABSTRACT

A thin film transistor (TFT) array substrate is provided. The thin film transistor (TFT) array substrate includes an insulating substrate, an oxide semiconductor layer formed on the insulating substrate and including an additive element, a gate electrode overlapping the oxide semiconductor layer, and a gate insulating layer interposed between the oxide semiconductor layer and the gate electrode, wherein the oxygen bond energy of the additive element is greater than that of a base element of the oxide semiconductor layer.

### CROSS-REFERENCE TO RELATED APPLICATION

This application claims priority from Korean Patent Application No. 10-2008-0133624 filed on Dec. 24, 2008 in the Korean Intellectual Property Office, the disclosure of which is incorporated herein by reference in its entirety.

### BACKGROUND OF THE INVENTION

1. Field of the Invention

The present invention relates to a thin film transistor array substrate and a method of fabricating the same, and more particularly, to a thin film transistor array substrate which can improve the stability and electrical properties of an oxide semiconductor layer, and a method of fabricating the thin film transistor array substrate.

2. Description of the Related Art

A liquid crystal display (LCD) is one of the most widely used flat panel displays. An LCD includes two panels provided with field-generating electrodes, and a liquid crystal (LC) layer interposed therebetween. The LCD displays images by applying voltages to the field-generating electrodes to rearrange LC molecules in the LC layer, which adjusts the amount of light transmitted.

In general, an LCD includes a thin film transistor (TFT) used as a switching element of each pixel. The TFT is a three-terminal device including a gate electrode to which a switching signal is applied, a source electrode to which a data voltage is applied, and a drain electrode through which the data voltage is output. The TFT may include an active layer formed between each of the gate electrode, the source electrode and the drain electrode. Here, the active layer included in the TFT is mainly made of amorphous silicon or polysilicon.

The TFT made of polysilicon having higher electron mobility than that of amorphous silicon exhibits several advantages, including a faster driving speed and a higher output current. However, the polysilicon TFT is disadvantageous compared to the amorphous silicon TFT in view of the cost and uniformity.

Accordingly, development of TFTs including an oxide semiconductor layer incorporating advantages of both amorphous silicon TFTs and polysilicon TFTs, is highly demanded. It is necessary to form an oxide semiconductor layer having a structure which can reduce generation of oxygen vacancy and increase stability.

### SUMMARY OF THE INVENTION

The present invention provides a thin film transistor array substrate which can improve the stability and electrical properties of an oxide semiconductor layer.

The present invention also provides a method of fabricating a thin film transistor array substrate which can improve the stability and electrical properties of an oxide semiconductor layer.

These and other objects of the present invention will be described in or be apparent from the following description of the preferred embodiments.

According to an aspect of the present invention, there is provided a thin film transistor (TFT) array substrate includes an insulating substrate, an oxide semiconductor layer formed on the insulating substrate and including an additive element, a gate electrode overlapping the oxide semiconductor layer, and a gate insulating layer interposed between the oxide semiconductor layer and the gate electrode, wherein the oxygen bond energy of the additive element is greater than that of a base element of the oxide semiconductor layer.

According to another aspect of the present invention, there is provided a method of fabricating a thin film transistor (TFT) array substrate including forming an oxide semiconductor layer on the insulating substrate and including an additive element; forming a gate electrode overlapping the oxide semiconductor layer; and forming a gate insulating layer interposed between the oxide semiconductor layer and the gate electrode, wherein the oxygen bond energy of the additive element is greater than that of a base element of the oxide semiconductor layer.

### BRIEF DESCRIPTION OF THE DRAWINGS

The above and other features and advantages of the present invention will become more apparent by describing in detail preferred embodiments thereof with reference to the attached drawings in which:

FIG. 1A is a layout view of a thin film transistor (TFT) array substrate according to a first embodiment of the present invention;

FIG. 1B is a cross-sectional view of the TFT array substrate taken along the line A-A′ of FIG. 1A;

FIGS. 2 through 6 are cross-sectional views showing sequential steps of a method of fabricating the TFT array substrate shown in FIG. 1A; and

FIG. 7 is a cross-sectional view of a TFT array substrate according to a second embodiment of the present invention.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the size and relative sizes of layers and regions may be exaggerated for clarity.

It will be understood that when an element or layer is referred to as being “on”, “connected to”, or “coupled to” another element or layer, it can be directly on, directly connected to, or directly coupled to the other element or layer or intervening elements or layers may be present. In contrast, when an element is referred to as being “directly on,” “directly connected to”, or “directly coupled to” another element or layer, there are no intervening elements or layers present. Like numbers refer to like elements throughout. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below.

Embodiments of the present invention are described herein with reference to cross-sectional illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. Thus, the regions illustrated in the figures are schematic in nature and their shapes are not intended to illustrate the precise shape of a region and are not intended to limit the scope of the present invention.

Hereinafter, exemplary embodiments of the present invention will be explained in detail with reference to the accompanying drawings.

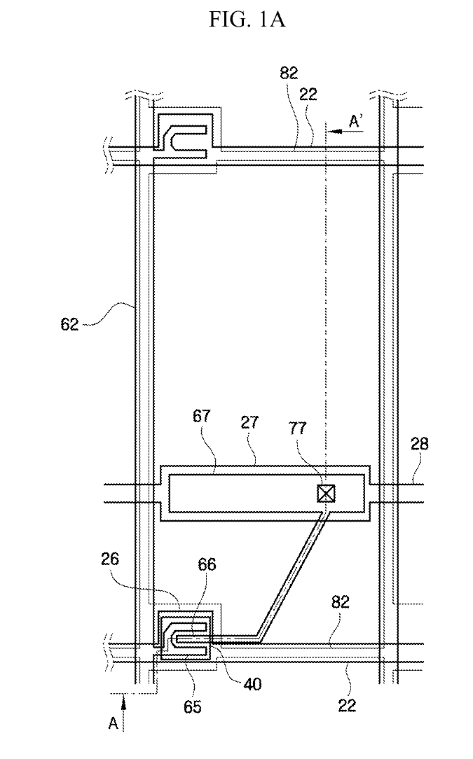

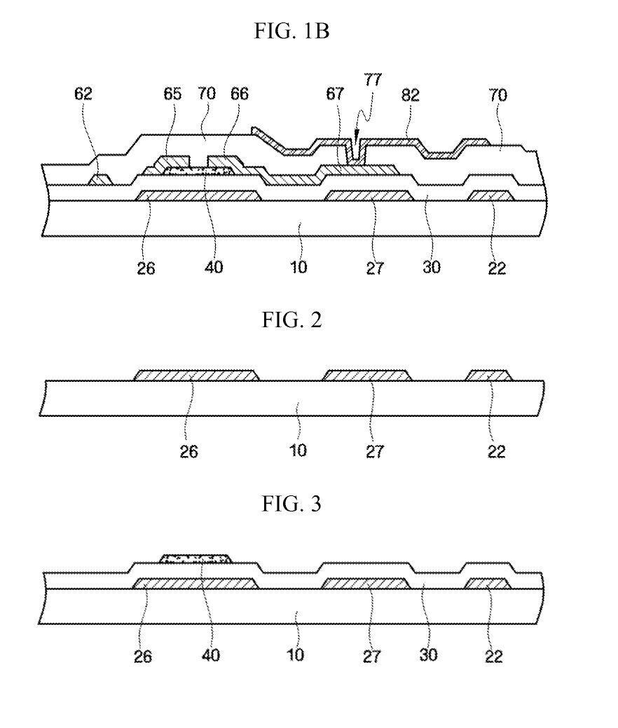

Hereinafter, a thin film transistor (TFT) array substrate according to a first embodiment of the present invention will be described with reference to FIGS. 1A and 1B. FIG. 1A is a layout view of a thin film transistor (TFT) array substrate according to a first embodiment of the present invention, and FIG. 1B is a cross-sectional view of the TFT array substrate taken along the line A-A′ of FIG. 1A.

Referring to FIGS. 1A and 1B, a plurality of gate wirings are formed on an insulating substrate 10 to transmit gate signals. Each gate wiring (22 and 26) includes a gate line 22 that extends in a transverse direction and a gate electrode 26 of a TFT that is connected to the gate line 22 to form a protrusion. A storage wiring (27 and 28) is formed on the insulating substrate 10 to transmit a storage signal. The storage wiring (27 and 28) includes a storage line 28 substantially parallel to the gate line 22 across a pixel region, and a storage electrode 27 wider than the storage line 28 and connected to the storage line 28.

The storage electrode 27 is wider than the storage line 28 and overlaps the drain electrode expanded part 67 that is connected to a pixel electrode 82, as described below, to form a storage capacitor for improving the electric charge retention ability of the pixel. The shape and position of the storage electrode 27 and the storage line 28 may vary, and the storage electrode 27 and the storage line 28 may not be formed if the storage capacitance that is generated due to the overlapping of the pixel electrode 82 and the gate line 22 is sufficiently high.

The gate wiring (22 and 26) and the storage wiring (27 and 28) may be made of an aluminum-based metal, such as aluminum (Al) and an aluminum alloy, a silver-based metal, such as silver (Ag) and a silver alloy, a copper-based metal, such as copper (Cu) or a copper alloy, a molybdenum-based metal, such as molybdenum (Mo) and a molybdenum alloy, chromium (Cr), titanium (Ti), or tantalum (Ta). Additionally, the gate wiring (22 and 26) and the storage wiring (27 and 28) may have a multi-layered structure including two conductive layers (not shown) having different physical properties. Of the two conductive layers, any one conductive layer is formed of metal having low resistivity, for example, the aluminum-based metal, the silver-based metal, or the copper-based metal, so as to reduce a signal delay or a voltage drop in the gate wiring (22, 26, 27 and 28). Another conductive layer may be formed of a substance having good contact features with zinc oxide (ZnO), ITO (indium tin oxide), and IZO (indium zinc oxide), such as a molybdenum-based metal, chromium, titanium, or tantalum. With respect to the above-mentioned combination, a structure that includes a lower chromium layer and an upper aluminum layer, or a structure that includes a lower aluminum layer and an upper molybdenum layer may be formed. However, the present invention is not limited thereto. The gate wiring (22 and 26) and the storage wiring (27 and 28) may be made of various types of metals, and conductors.

A gate insulating layer 30 is formed on the insulating substrate 10 and the gate wiring (22 and 26). The gate insulating layer 30 is made of silicon oxide (SiOₓ), silicon nitride (SiNₓ), or silicon oxynitride (SiON). In order to improve layer characteristics, the gate insulating layer 30 may be formed using a dopant of Group III or V elements of the periodic table.

An oxide semiconductor layer 40 including at least one of Zn and Sn as a base element and an additive element are formed on the gate insulating layer 30. Here, the additive element may include at least one of hafnium (Hf) and tantalum (Ta), for example. The oxide semiconductor layer 40 may use an oxide including, for example, at least one of, ZnHfO, ZnTaO, SnHfO, SnTaO, ZnSnHfO, ZnSnTaO, and ZnSnHfTaO. The oxide semiconductor layer 40 has excellent semiconductor characteristics, including about 2 to 100 times higher electron effective mobility of charges than that of hydrogenated amorphous silicon.

The oxide semiconductor layer 40 has an oxygen-containing oxide structure, so that when an oxide of the oxide semiconductor layer 40 is reduced, oxygen deficiency may be caused to the oxide semiconductor layer 40. The oxygen deficiency in the oxide semiconductor layer 40 generates oxygen vacancies in the oxide semiconductor layer 40. The oxygen vacancies may increase a carrier concentration of the oxide semiconductor layer 40. The increased carrier concentration of the oxide semiconductor layer 40 may change electrical properties of the oxide semiconductor layer 40, for example, shifting a threshold voltage (Vth) of an oxide TFT into a negative voltage, transforming the oxide semiconductor layer 40 into a conductor, causing a current leakage.

The oxide semiconductor layer 40 is brought into contact with the gate insulating layer 30 overlying the oxide semiconductor layer 40 and a passivation layer 70 underlying the oxide semiconductor layer 40. The gate insulating layer 30 and the passivation layer 70 may be made of silicon oxide (SiOₓ), silicon nitride (SiNₓ), or silicon oxynitride (SiON), so that an element contained in the gate insulating layer 30 and the passivation layer 70, e.g., Si, binds with oxygen, to form oxygen vacancies in the oxide semiconductor layer 40.

Another possibility to generate oxygen vacancies in the oxide semiconductor layer 40 is associated with chemical materials while performing a process using various chemical materials with respect to the oxide semiconductor layer 40. For example, after forming the oxide semiconductor layer 40, the oxide semiconductor layer 40 may be etched in order to form a source electrode 65 and a drain electrode 66. At this time, a mixed gas of CF₄, CHF₃, CH₂F₂, CH₃F, C₂F₆, SF₆, or CₙFₙ₊₄ and O₂ may be used as an etching gas. The etching gas may cause oxygen deficiency to the semiconductor layer 40, thereby generating the oxygen vacancies. In order to stabilize the boding structure of oxygen in the oxide semiconductor layer 40, an additive element may be selectively added to the oxide semiconductor layer 40.

The additive element added to the oxide semiconductor layer 40 may be an element capable of reinforcing the oxygen-bonding structure of the oxide semiconductor layer 40. For example, the additive element should be selected such that the additive element-oxygen bond energy is higher than the oxygen bond energy of a base element of the oxide semiconductor layer 40. Throughout the specification, the term “oxygen bond energy” means a bonding force of a given atom to an oxygen atom.

Table 1 summarizes the oxygen bond energy of elements added at room temperature.

TABLE 1

| Element | Oygen Bond Energy (KJ/mol) |
|---|---|
| Zn | 159 |
| In | 320 |
| Sn | 532 |
| Ga | 354 |
| Si | 398.05 |
| Hf | 590.44 |
| Ta | ~800 |

The base element of the oxide semiconductor layer 40 may include at least one of Zn and Sn. Referring to Table 1, the oxygen bond energy of the base element Zn in the oxide semiconductor layer 40 is 159 KJ/mol, and the oxygen bond energy of the base element Sn of the oxide semiconductor layer 40 is 532 KJ/mol. Therefore, Hf or Ta may be selected as the additive element such that the oxygen bond energy of the additive element is larger than that of the base element of the oxide semiconductor layer 40.

Meanwhile, when the gate insulating layer 30 and the passivation layer 70 are made of silicon oxide (SiOₓ), silicon nitride (SiNₓ), or silicon oxynitride (SiON), Hf or Ta is added as the additive element to the oxide semiconductor layer 40, thereby prevent oxygen vacancies from being generated due to Si in the gate insulating layer 30 and the passivation layer 70.

The constituent elements of the oxide semiconductor layer 40 have good ohmic contact characteristics with data wiring (62, 65, 66, and 67), obviating the necessity of a separate ohmic contact layer, thereby reducing the processing time. In addition, the oxide semiconductor layer 40 is in an amorphous phase but has a high effective mobility of charges, so that it can be applied to the conventional technique for amorphous silicon production, which is useful for large-screen area display devices.

In the oxide TFT according to the present embodiment, the oxide semiconductor layer 40 and the data wiring (62, 65, 66 and 67) have different pattern shapes. However, when a 4-mask process is employed, the oxide semiconductor layer 40 and the data wiring (62, 65, 66 and 67) may be patterned in the same shape, except for a channel region of the oxide TFT. This is because the oxide semiconductor layer 40 and the data wiring (62, 65, 66 and 67) are patterned using a single etch mask. While a structure manufactured using a 5-mask process is illustrated in the present embodiment, the above exemplary embodiment is only one implementation of the present invention and other implementation is also possible by selecting a different structure manufactured by a process different from the 5-mask process, such as a 3-mask or a 4-mask process.

The data wiring (62, 65, 66 and 67) is formed on the oxide semiconductor layer 40 and the gate insulating layer 30. The data wiring (62, 65, 66 and 67) may include the data line 62 that crosses the gate line 22 in a longitudinal direction to define the pixel, the source electrode 65 that is branched from the data line 62 and extends to an upper part of the oxide semiconductor layer 40, the drain electrode 66 that is separated from the source electrode 65 and formed on an upper part of the oxide semiconductor layer 40 which is opposite to the source electrode 65 with respect to channel portions of the gate electrode 26 or the oxide TFT, and the drain electrode pad 67 that extends from the drain electrode 66 to overlap the storage electrode 27 and has a large area.

The data wiring (62, 65, 66 and 67) may be made of a material that directly contact the oxide semiconductor layer 40 and thus form a good ohmic contact with them. If the data wiring (62, 65, 66 and 67) is made of a material having a work function smaller than that of a material of the oxide semiconductor layer 40, the ohmic contact can be formed between the two material layers.

Therefore, in order to form the ohmic contact with the oxide semiconductor layer 40, the data wiring (62, 65, 66 and 67) may be formed as a single layer or multiple layers made of Ni, Co, Ti, Ag, Cu, Mo, Al, Be, Nb, Au, Fe, Se, or Ta. Alternatively, the data wiring (62, 65, 66 and 67) may be formed of an alloy of any one or more of the above metals and at least one element selected from the group consisting of Ti, Zr, W, Ta, Nb, Pt, Hf, O and N.

Meanwhile, if the oxide semiconductor layer 40 directly contacts a metal such as Al, Cu or Ag, characteristics of the oxide TFT, which uses the metal as the data wiring, and/or the ohmic contact characteristics between the oxide TFT and ITO or IZO used as the pixel electrode 82 may deteriorate due to reaction or diffusion between the oxide semiconductor layer 40 and the directly contacting metal. Therefore, the data wiring (62, 65, 66 and 67) may be formed to have a double-layered structure or a triple-layered structure.

If Al or an alloy of Al and any one of Nd, Sc, C, Ni, B, Zr, Lu, Cu and Ag is used for the data wiring, the data wiring (62, 65, 66 and 67) may be formed as multiple layers including different types of layers formed on and/or under Al or the Al alloy. For example, may be formed as a double layer comprised of any one of Mo(Mo alloy)/Al(Al alloy), Ti(Ti alloy)/Al(Al alloy), Ta(Ta alloy)/Al(Al alloy), Ni(Ni alloy)/Al(Al alloy) and Co(Co alloy)/Al(Al alloy) or a triple layer comprised of any one of Ti(Ti alloy)/Al(Al alloy)/Ti(Ti alloy), Ta(Ta alloy)/Al(Al alloy)/Ta(Ta alloy), Ti(Ti alloy)/Al(Al alloy)/TiN, Ta(Ta alloy)/Al(Al alloy)/TaN, Ni(Ni alloy)/Al(Al alloy)/Ni(Ni alloy), Co(Co alloy)/Al(Al alloy)/Co(Co alloy) and Mo(Mo alloy)/Al(Al alloy)/Mo(Mo alloy). In this case, the alloys may also contain Mo, W, Nb, Zr, V, O or N.

If Cu or a Cu alloy is used for the data wiring (62, 65, 66 and 67), there is no significant problem with the ohmic contact characteristics of the data wiring (62, 65, 66 and 67) with the pixel electrode 82. Therefore, the data wiring (62, 65, 66 and 67) may be formed as a multiple layer including a Mo, Ti or Ta layer between the Cu or Cu-alloy layer and the oxide semiconductor layer 40. For example, the data wiring may be a multiple layer such as Mo(Mo alloy)/Cu, Ti(Ti alloy)/Cu, TiN(TiN alloy)/Cu, Ta(Ta alloy)/Cu, or TiOx/Cu.

The source electrode 65 at least partially overlaps the oxide semiconductor layer 40, and the drain electrode 66 at least partially overlaps the oxide semiconductor layer 40 to face the source electrode 65 with respect to the channel portion of the oxide TFT.

The drain electrode pad 67 overlaps the storage electrode 27, and thus the drain electrode pad 67 and the storage electrode 27 form a storage capacitor with the gate insulating film 30 interposed therebetween. If the storage electrode 27 is not be formed, the drain electrode pad 67 may be formed.

The passivation layer 70 is formed on the data wiring (62, 65, 66, and 67) and on the oxide semiconductor layer 40 exposed by the data wiring (62, 65, 66, and 67). Since the passivation layer 70 contacts the oxide semiconductor layer 40, it may be formed of silicon oxide (SiOₓ), silicon nitride (SiNₓ), or silicon oxynitride (SiON), like the gate insulating layer 30. In order to improve layer characteristics of the passivation layer 70, the passivation layer 70 may be formed using a dopant of Group III or V elements of the periodic table.

A contact hole 77 exposing the drain electrode pad 67 is formed in the passivation layer 70. The pixel electrode 82 is electrically connected to the drain electrode pad 67 by the contact hole 77. The pixel electrode 82 may be made of a transparent conductor, such as ITO or IZO, or a reflective conductor such as Al.

The pixel electrode 82 to which a data voltage is applied generates an electric field in conjunction with a common electrode of an upper substrate to control alignment of the liquid crystal molecules of the liquid crystal layer between the pixel electrode 82 and the common electrode.

Hereinafter, a method of fabricating the thin film transistor substrate according to the first embodiment of the present invention will be described in detail with reference to FIGS. 1A to 6.

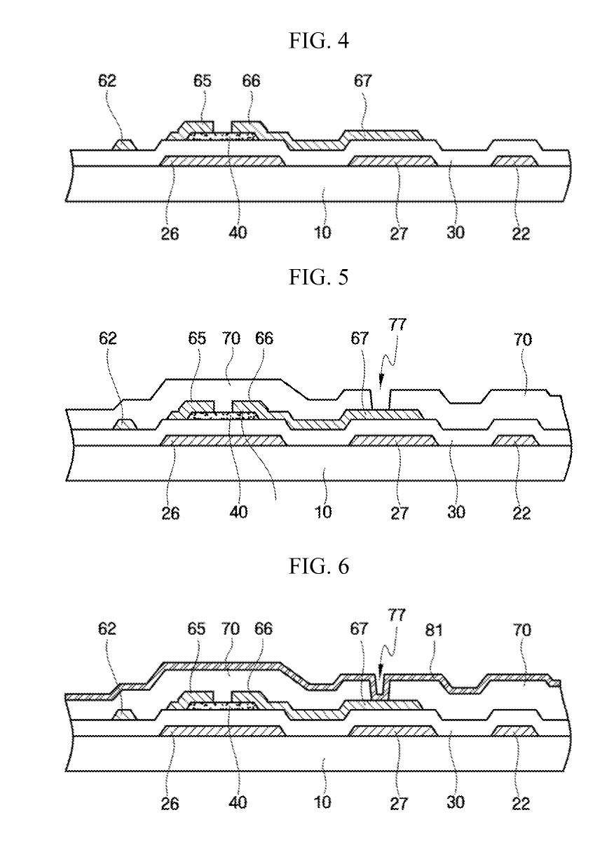

FIGS.2 through 6 are cross-sectional views showing sequential steps of a method of fabricating the TFT array substrate shown in FIG. 1A.

First, as shown in FIGS. 1A and 2, the gate line 22, the gate electrode 26, the storage electrode 27 and the storage line 28 are formed on the insulating substrate 10.

The insulating substrate 10 may be made of, for example, glass such as soda lime glass or borosilicate glass, or plastics.

In order to form the gate wiring (22 and 26), a conductive layer for gate wirings is first formed on the insulating substrate 10. The conductive layer is deposited using, for example, a sputtering process. Here, if the insulating substrate 10 is made of soda lime glass, which is weak against heat, a low-temperature sputtering process may be used.

Next, the conductive layer for gate wirings is patterned using a wet-etching or dry-etching process to form the gate wiring (22 and 26). In the wet-etching process, phosphoric acid, nitric acid or citric acid may be used as the etching gas. In the dry-etching process, Cl₂ or BCl₃ may be used as the etching gas.

Referring to FIGS. 1A and 3, the gate insulating film 30 is deposited on the exposed parts of the insulation substrate 10, on the gate wiring (22 and 26) using, for example, plasma enhanced chemical vapor deposition (PECVD) or reactive sputtering.

Next, the oxide semiconductor layer 40 is formed on the gate insulating film 30 by, for example, sputtering.

The etching step of the oxide semiconductor layer 40 may be performed separately from the subsequent process for the data wiring (62, 65, 66 and 67), like in the present embodiment. In alternative embodiments, however, in order to reduce the number of masks used in the process, the oxide semiconductor layer 40 and the data wiring (62, 65, 66 and 67) may be simultaneously performed.

An oxide semiconductor material is formed on the entire surface of the gate insulating layer 30 and then patterned, thereby forming the oxide semiconductor layer 40. As described above, the oxide semiconductor layer 40 may include at least one of Zn and Sn as a base element and an additive element. The additive element may include at least one of Hf and Ta, for example. The oxide semiconductor layer 40 may use an oxide including, for example, at least one of, ZnHfO, ZnTaO, SnHfO, SnTaO, ZnSnHfO, ZnSnTaO, and ZnSnHfTaO. The aforementioned structure of the oxide semiconductor layer 40 is reinforced by selecting the additive element such that the additive element-oxygen bond energy is higher than the oxygen bond energy of the base element of the oxide semiconductor layer 40. Accordingly, oxygen vacancies of the oxide semiconductor layer 40, which may generated during the etching step, may be prevented.

Next, as shown in FIG. 5, the passivation layer 70 is formed using, for example, PECVD or reactive sputtering. The passivation layer 70 is patterned by photolithography to form the contact hole 77 exposing the drain electrode pad 67.

Referring to FIG. 6, a conductive layer 81 for a pixel electrode, which is connected to a portion of the data wiring (62, 65, 66 and 67) is formed on the passivation layer 70. The conductive layer 81 may be made of a transparent conductor, such as ITO or IZO, or a reflective conductor such as Al.

Referring to FIGS. 6 and 1B, the conductive layer 81 is patterned to form the pixel electrode 82. While the TFT array substrate having a bottom gate structure in which a gate electrode is formed below an oxide semiconductor layer has been described in the above-described embodiments, the present invention is not limited thereto. The present invention can also be applied to a TFT array substrate having a top gate structure in which a gate electrode is formed above an oxide semiconductor layer.

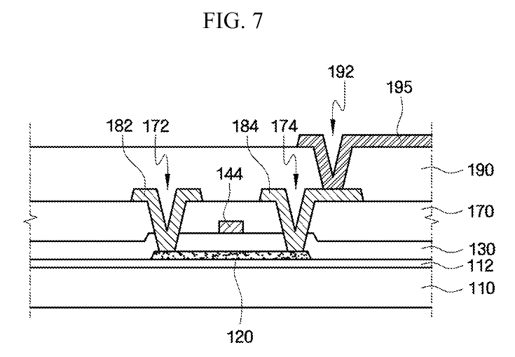

Hereinafter, a TFT array substrate having a top gate structure according to an exemplary embodiment of the present invention will be described with reference to FIG. 7 A TFT array substrate according to a second embodiment of the present invention will now be described in detail with reference to FIG. 7. FIG. 7 is a cross-sectional view of a TFT array substrate according to a second embodiment of the present invention.

A buffer layer 112 made of silicon oxide (SiOₓ) or silicon nitride (SiNₓ) is formed on an insulating substrate 110. The buffer layer 112 may be made of silicon oxide (SiOₓ), silicon nitride (SiNₓ), or silicon oxynitride (SiON).

An oxide semiconductor layer 120 including at least one of Zn and Sn as a base element and an additive element are formed on the buffer layer 112. Here, the additive element may include at least one of Hf and Ta, for example. The oxide semiconductor layer 120 may use an oxide including, for example, at least one of, ZnHfO, ZnTaO, SnHfO, SnTaO, ZnSnHfO, ZnSnTaO, and ZnSnHfTaO.

A gate insulating layer 130 is formed on the insulating substrate 110 and the oxide semiconductor layer 120. The gate insulating layer 130 may be made of silicon oxide (SiOₓ), silicon nitride (SiNₓ), or silicon oxynitride (SiON), like the buffer layer 112.

A gate electrode 144 overlapping the oxide semiconductor layer 120 is formed on the gate insulating layer 130.

A first interlayer insulating film 170 is formed on the gate insulating layer 130 and the gate electrode 144. The first interlayer insulating film 170 is generally made of silicon oxide (SiOₓ), silicon nitride (SiNₓ), or silicon oxynitride (SiON), using chemical vapor deposition (CVD). A pair of contact holes 172 and 174 partially exposing the oxide semiconductor layer 120 positioned at both sides of the gate electrode 144, are formed in the first interlayer insulating film 170 and the gate insulating layer 130.

A source electrode 182 and a drain electrode 184 electrically connected to the oxide semiconductor layer 120 through the pair of contact holes 172 and 174 are formed on the first interlayer insulating film 170.

A second first interlayer insulating film 190 made of, for example, an organic substance having good planarization properties and photosensitivity is formed on the source electrode 182, the drain electrode 184, and the first interlayer insulating film 170. The second first interlayer insulating film 190 may be formed of organic substance, for example, acryl resin, using spin coating. A contact hole 192 exposing the drain electrode 174 is formed in the second first interlayer insulating film 190.

A pixel electrode 195, made of a transparent material and connected to the drain electrode 174 through the contact hole 192, is formed on the second first interlayer insulating film 190.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A thin film transistor (TFT) array substrate comprising:
an insulating substrate;
an oxide semiconductor layer formed on the insulating substrate and including an additive element;
a gate electrode overlapping the oxide semiconductor layer; and
a gate insulating layer interposed between the oxide semiconductor layer and the gate electrode,
wherein the oxygen bond energy of the additive element is greater than that of a base element of the oxide semiconductor layer.

2. The TFT array substrate of claim 1, wherein the base element of the oxide semiconductor layer includes at least one of Zn and Sn.

3. The TFT array substrate of claim 1, wherein the additive element includes at least one of Hf and Ta.

4. The TFT array substrate of claim 3, wherein the oxide semiconductor layer includes at least one structure selected from the group consisting of ZnHfO, ZnTaO, SnHfO, SnTaO, ZnSnHfO, ZnSnTaO, and ZnSnHfTaO.

5. The TFT array substrate of claim 1, wherein the oxygen bond energy of the additive element is greater than that of the gate insulating layer.

6. The TFT array substrate of claim 1, further comprising a passivation layer on the oxide semiconductor layer, wherein the oxygen bond energy of the additive element is greater than that of the passivation layer.

7. The TFT array substrate of claim 6, wherein the passivation layer includes at least one of silicon oxide (SiOₓ), silicon nitride (SiNₓ), and silicon oxynitride (SiON).

8. A method of fabricating a thin film transistor (TFT) array substrate comprising:
forming an oxide semiconductor layer on the insulating substrate and including an additive element;
forming a gate electrode overlapping the oxide semiconductor layer; and
forming a gate insulating layer interposed between the oxide semiconductor layer and the gate electrode,
wherein the oxygen bond energy of the additive element is greater than that of a base element of the oxide semiconductor layer.

9. The method of claim 8, wherein the oxygen bond energy of the additive element is greater than that of the gate insulating layer.

10. The method of claim 8, wherein the additive element includes at least one of Hf and Ta.

11. The TFT array substrate of claim 10, wherein the oxide semiconductor layer includes at least one structure selected from the group consisting of ZnHfO, ZnTaO, SnHfO, SnTaO, ZnSnHfO, ZnSnTaO, and ZnSnHfTaO.

12. The TFT array substrate of claim 8, wherein the oxygen bond energy of the additive element is greater than that of the gate insulating layer.

13. The TFT array substrate of claim 8, further comprising forming a passivation layer on the oxide semiconductor layer, wherein the oxygen bond energy of the additive element is greater than that of the passivation layer.

14. The TFT array substrate of claim 13, wherein the passivation layer includes at least one of silicon oxide (SiOₓ), silicon nitride (SiNₓ), and silicon oxynitride (SiON).
